(19) United States
(12) Patent Application Publication
(10) Pub. No.: US 2009/0115458 A1
(43) Pub. Date: May 7, 2009

(54) CMOS COMPARATOR WITH HYSTERESIS

(76) Inventors: Frank Carr, New Coast, CA (US); Ahmed A. Emira, Lake Forest, CA (US)

Correspondence Address: Rahman LLC, 10025 Governor Warfield Parkway, Suite 110, Columbia, MD, 21044, US

(21) Appl. No.: 11/936,125

(22) Filed: Nov. 7, 2007

(51) Int. Cl. H03K 19/20; H03K 19/0948

(52) U.S. Cl. 326/122

(57) ABSTRACT

A complementary metal oxide semiconductor (CMOS) comparator circuit includes a plurality of p-type metal-oxide-semiconductor (PMOS) transistors receiving an input voltage signal, a plurality of n-type metal-oxide-semiconductor (NMOS) transistors operatively connected to the PMOS transistors and adapted to receive the input voltage signal, and an inverter adapted to invert the input voltage signal into an output voltage signal. An effective aspect ratio of the PMOS and NMOS transistors may be dependent on the level of the output voltage signal from the inverter. When a digital output of the inverter is “1”, the effective aspect ratio of the NMOS transistor is increased by turning on a second NMOS transistor, and a threshold voltage of the inverter is decreased.

### BACKGROUND

1. Technical Field

The embodiments herein generally relate to electrical circuits, and, more particularly, to a complementary metal oxide semiconductor (CMOS) comparator circuit with a sufficient hysteresis window.

2. Description of the Related Art

A digital input-output (IO) pad is a part of an integrated circuit chip for communicating information to and from circuits. The number of IO pads may limit the number of signal lines within the integrated circuit that can be accessed to transmit output information or receive input information during operation of the chip. A digital core voltage (V_{CORE}) is the power supply voltage needed by a digital circuit or device containing a processing core. The amount of power the device uses, and thus the amount of heat it dissipates, is a product of the digital core voltage and the current it draws. A static current is the amount of current used by a device when it is inactive but not powered down.

A digital IO pad in an integrated circuit may include a receiver (Rx) when it is configured as an input pad, and a transmitter (Tx) when it is configured as an output pad. They may be input only, or output only. When a pad is configured as an input pad, the receiver (Rx) is turned on while the transmitter (Tx) (e.g., if it is an IO pad) is turned off. FIG. 1 illustrates an input-output pad 100 having a receiver (Rx) 102 and a transmitter (Tx driver) 104. The receiver (Rx) 102 may perform voltage level shifting for the IO voltage levels to the internal digital core voltage levels. The receiver (Rx) 102 and the transmitter (Tx driver) 104 may have built in drivers. A CMOS comparator is an analog circuit building block using p-type metal-oxide-semiconductor (PMOS) and n-type metal-oxide-semiconductor (NMOS) transistors wired together in a balanced manner for detecting the level of an input signal relative to a preset threshold value. If hysteresis is added to the comparator characteristics, it exhibits two threshold values V_{TL} and V_{TH} that are separated by a small voltage.

Hysteresis width is the difference between the threshold voltages of a main inverter of the CMOS comparator in the two cases when the logic output is “1” or “0”. Due to various noise sources external to the integrated circuits, a small noise may be injected at the input. Furthermore, a false trigger may occur while the receiver (Rx) 102 transitions from a logic “0” to “1” or from a “1” to “0”. However, there remains a need for a CMOS comparator circuit with no static currents and a sufficient hysteresis window that can be used in applications such as IO pads and relaxation oscillators.

### SUMMARY

In view of the foregoing, an embodiment provides a complementary metal oxide semiconductor (CMOS) comparator circuit includes a plurality of p-type metal-oxide-semiconductor (PMOS) transistors receiving an input voltage signal, a plurality of n-type metal-oxide-semiconductor (NMOS) transistors operatively connected to the PMOS transistors and adapted to receive the input voltage signal, and an inverter adapted to invert the input voltage signal into an output voltage signal. An effective aspect ratio of the PMOS and NMOS transistors may be dependent on the level of the output voltage signal from the inverter. When a digital output of the inverter is “1”, the effective aspect ratio of the NMOS transistor is increased by turning on a second NMOS transistor, and a threshold voltage of the inverter is decreased when the digital output of the inverter is “0”, the effective aspect ratio of the PMOS is increased by turning on a second PMOS transistor, and the threshold voltage of the inverter is increased.

A third PMOS transistor may be operatively connected in parallel with the first PMOS transistor, and a third NMOS transistor may be operatively connected in parallel with the first NMOS transistor. The second NMOS transistor may be coupled to the second PMOS transistor. The second PMOS transistor and the second NMOS transistor output the output voltage. The second PMOS transistor may be switched on to increase a threshold voltage of the inverter when the output voltage is low. A supply voltage may be applied to the first PMOS transistor.

The input voltage signal may be adapted to be increased from zero to a first threshold level of the inverter during a first time period at which point the output voltage signal becomes equal to the supply voltage. The input voltage signal may be further adapted to increase to become equal to the supply voltage during a second time period. The output voltage signal remains equal to the supply voltage. The input voltage signal may be further adapted to decrease from the supply voltage until a second threshold level of the inverter is reached during a third time period. A difference between the first threshold level of the inverter and the second threshold level of the inverter equals a hysteresis width of the CMOS comparator circuit.

In another aspect, an input-output pad includes a complementary metal oxide semiconductor (CMOS) comparator with a hysteresis window, the CMOS comparator includes a first p-type metal-oxide-semiconductor (PMOS) transistor receiving an input voltage, an inverter coupled to a gate of the first PMOS transistor, a second PMOS transistor operatively connected in parallel to the first PMOS transistor, the second PMOS transistor is coupled to the inverter, a first n-type metal-oxide-semiconductor (NMOS) transistor receiving an input voltage, and a second NMOS transistor is operatively connected in parallel to the first NMOS transistor, the second NMOS transistor is coupled to the inverter and the second PMOS transistor, the second NMOS transistor outputs an output voltage. The second PMOS transistor is switched on to increase a threshold voltage of the inverter when the output voltage is zero, and the second NMOS transistor is switched on to decrease a threshold voltage of the inverter when the output voltage is equal to a supply voltage.

A third PMOS transistor may be operatively connected in parallel with the first PMOS transistor, a third NMOS transistor may be operatively connected in parallel with the first NMOS transistor. The supply voltage may be applied to the first PMOS transistor and the third PMOS transistor. The second NMOS transistor switches on when the input voltage reaches the supply voltage. The input voltage may be adapted to increase from zero to a first threshold level of the inverter during a first time period at which point the output voltage becomes equal to the supply voltage.

The input voltage may be adapted to increase from zero to a first threshold level of the inverter during a first time period at which point the output voltage becomes equal to the supply voltage. The input voltage may be further adapted to increase to become equal to the supply voltage during a second time period, wherein the output voltage remains equal to the supply voltage. The input voltage may be further adapted to decrease from the supply voltage until a second threshold level of the inverter is reached during a third time period. A difference between the first threshold level of the inverter and the second threshold level of the inverter may equal a hysteresis width of the CMOS comparator.

In yet another aspect, a method of providing a hysteresis window in a complementary metal oxide semiconductor (CMOS) comparator circuit includes applying a low input voltage to a first p-type metal-oxide-semiconductor (PMOS) transistor and a first n-type metal-oxide-semiconductor (NMOS) transistor, coupling an inverter to an output of the first PMOS transistor and an output of the first NMOS transistor, coupling a second NMOS transistor in parallel with the first NMOS transistor, coupling a second PMOS transistor in parallel with the first PMOS transistor, the second PMOS transistor and the second NMOS transistor coupled to an output voltage, and switching on the second PMOS transistor when the output voltage is low.

A third PMOS transistor may be coupled to the second PMOS transistor. A third NMOS transistor may be coupled to the second NMOS transistor. A supply voltage may be applied to the first PMOS transistor and the third PMOS transistor. The input voltage may be increased to reach a first threshold voltage of the inverter. The input voltage may be increased to reach the supply voltage. Second NMOS transistor may be switched on when the input voltage reaches the supply voltage. The input voltage may be decreased to reach a second threshold voltage of the inverter.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 illustrates an input-output pad having a receiver and a transmitter;

FIG. 2 illustrates a CMOS comparator circuit having a first PMOS transistor, a second PMOS transistor, a third PMOS transistor, a first NMOS transistor, a second NMOS transistor, a third NMOS transistor, an input voltage, an output voltage, a supply voltage, a ground, a voltage (Vx), and an inverter according to an embodiment herein;

FIG. 3 illustrates the CMOS comparator circuit of FIG. 2 when the input voltage is equal to zero, the first, second, and third PMOS transistors are on, the first, second, and third NMOS transistors are off, and the output voltage is equal to zero according to an embodiment herein;

FIG. 4 illustrates the CMOS comparator circuit of FIG. 2 when the input voltage is equal to the supply voltage, the first, second, and third PMOS transistors are off, the first, second, and third NMOS transistors are on, and the output voltage is equal to the supply voltage according to an embodiment herein;

FIG. 5 is a hysteresis graph illustrating a first threshold voltage, a second threshold voltage, and a hysteresis width of the CMOS comparator circuit of FIG. 2 according to an embodiment herein; and

FIGS. 6A and 6B are flow diagrams illustrating a method of providing a hysteresis window in a CMOS comparator circuit according to an embodiment herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein. As mentioned, there remains a need for a CMOS comparator circuit with no static currents and a sufficient hysteresis window that can be used in applications such as IO pads and relaxation oscillators.

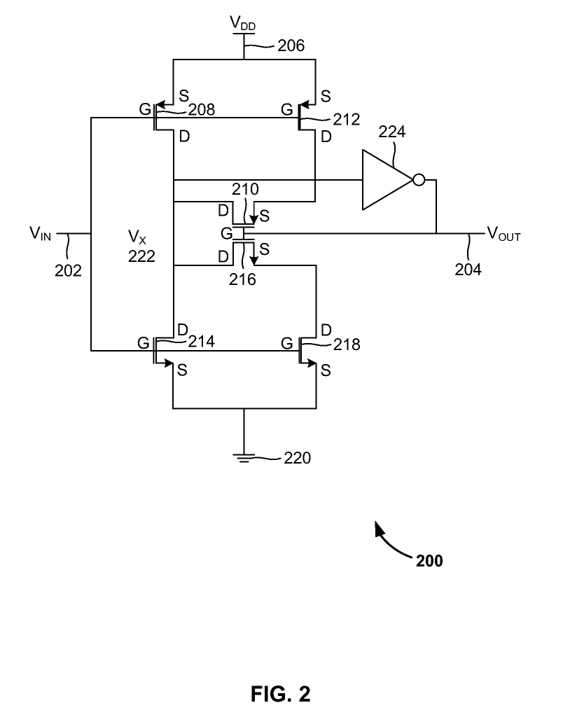

The embodiments herein achieve this by providing a CMOS comparator circuit that includes a first PMOS transistor coupled to an input voltage, an inverter coupled to a drain of the first PMOS transistor, a second PMOS transistor operatively connected in parallel to the first PMOS transistor, the second PMOS transistor coupled to the inverter, a first NMOS transistor coupled to the input voltage, a second NMOS transistor operatively connected in parallel to the first NMOS transistor, the second NMOS transistor coupled to the inverter, the second PMOS transistor switched on to increase the threshold voltage of the inverter when an output voltage of the CMOS comparator circuit is low. Referring now to the drawings, and more particularly to FIGS. 2 through 6(B), where similar reference characters denote corresponding features consistently throughout the figures, there are shown preferred embodiments.

FIG. 2 illustrates a CMOS comparator circuit 200 having an input voltage V_{IN} 202, an output voltage V_{OUT} 204, a supply voltage V_{DD} 206, a first PMOS transistor 208, a second PMOS transistor 210, a third PMOS transistor 212, a first NMOS transistor 214, a second NMOS transistor 216, a third NMOS transistor 218, ground 220, a voltage V_{X} 222 and an inverter 224 according to an embodiment herein. The input voltage 202 is input into the first PMOS transistor 208. The second PMOS transistor 210 is operatively connected in parallel to the first PMOS transistor 208. The output voltage 204 is output from the second PMOS transistor 210 and the second NMOS transistor 216. The supply voltage 206 is applied to the first PMOS transistor 208 and the third PMOS transistor 212.

The input voltage 202 is input into the first NMOS transistor 214. The second NMOS transistor 216 is operatively connected in parallel to the first NMOS transistor 214. The third PMOS transistor 212 is operatively connected in parallel with the first PMOS transistor 208 and the second PMOS transistor 210. The third NMOS transistor 218 is operatively connected in parallel with the first NMOS transistor 214 and the second NMOS transistor 216. In addition, the second PMOS transistor 210 is coupled to the second NMOS transistor 216. The first NMOS transistor 214 and the third NMOS transistor 218 are operatively connected to ground 220. The inverter 224 is coupled to a gate of the first PMOS transistor 208 and also to the second PMOS transistor 210 and the second NMOS transistor 216.

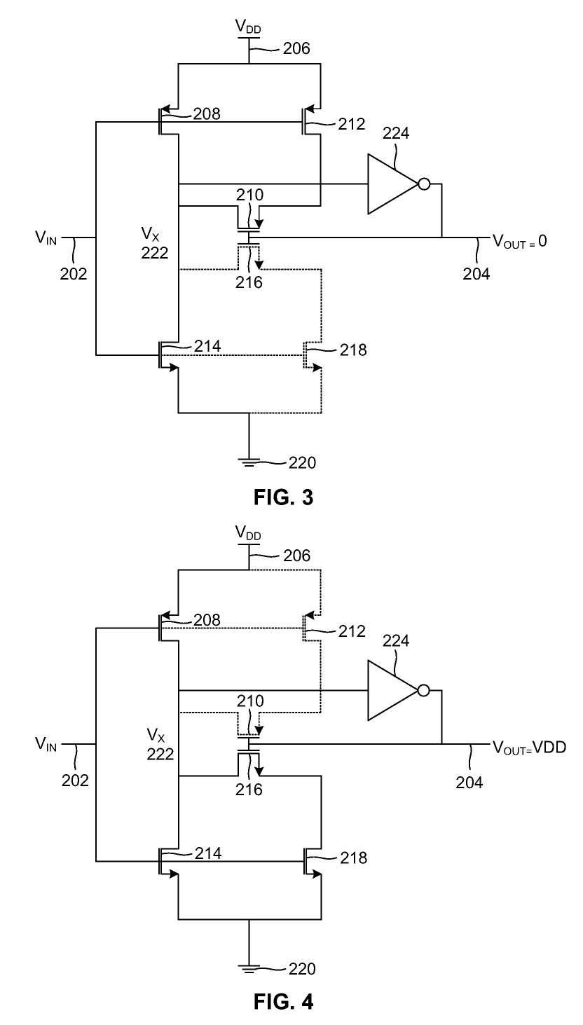

FIG. 3 illustrates the CMOS comparator circuit 200 of FIG. 2 when the input voltage V_{IN} 202 is equal to zero; the first PMOS transistor 208, the second PMOS transistor 210, and the third PMOS transistor 212 are on; the first NMOS transistor 214, the second NMOS transistor 216, and the third NMOS transistor 218 are off, and the output voltage V_{OUT} 204 is equal to zero. When the input voltage V_{IN} 202 is low (e.g., equal to zero), the first NMOS transistor 214 turns off and the first PMOS transistor 208 turns on. Therefore, the voltage V_{X} becomes low (e.g., equal to zero) and the output of the inverter 224 becomes high (e.g., equal to the supply voltage V_{DD}). Thus, the second PMOS transistor 210 and the third PMOS transistor 212 also turn on (e.g., forward biased), since they are in parallel with the first PMOS transistor 208. Also, the second NMOS transistor 216 and the third NMOS transistor 218, which are in parallel with the first NMOS transistor 214 turn off (e.g., reverse biased), and there is no current flow (e.g., as shown using dotted lines in FIG. 3) from the first NMOS transistor 214, second NMOS transistor 216, and the third NMOS transistor 218.

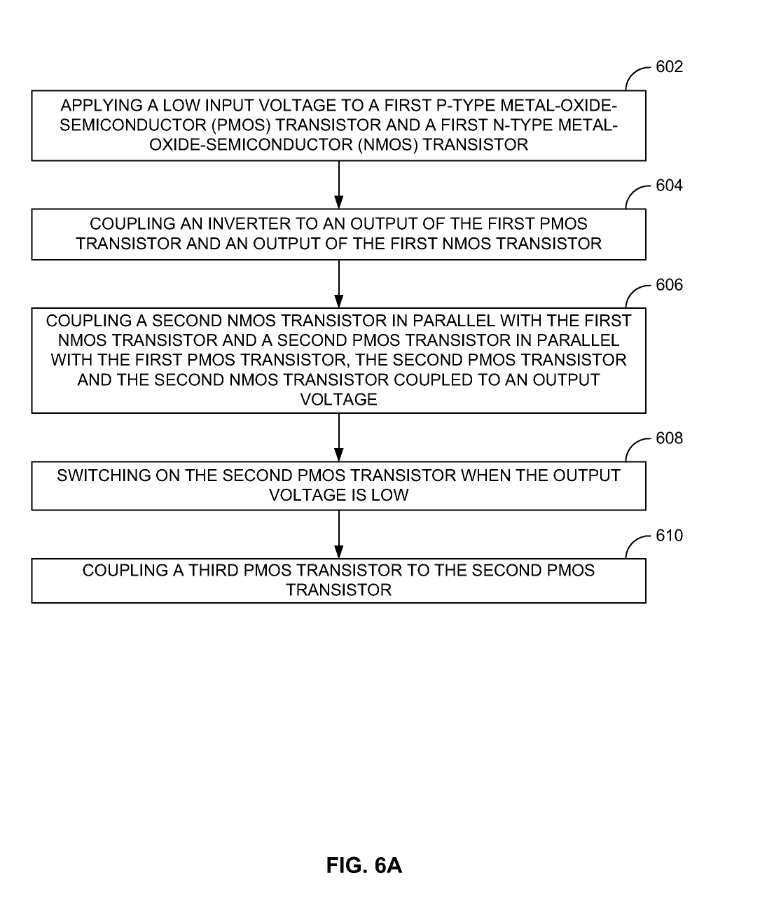

When the value of the MOSFET gate voltage of the first PMOS transistor 208 is equal to zero, the voltage V_{X} 222 is equal to the supply voltage V_{DD} 206. Since the voltage V_{X} 222 reaches the input of the inverter 224, the output voltage V_{OUT} 206 is equal to zero. Assuming Aₚ₁, Aₚ₂, and Aₚ₃ are the aspect ratios of the first PMOS transistor 208, the third PMOS transistor 212, and the second PMOS transistor 210 respectively, and Aₙ₁, Aₙ₂, and Aₙ₃ are the aspect ratios of the first NMOS transistor 214, the third NMOS transistor 218, and the second NMOS transistor 216 respectively. Therefore, the PMOS effective aspect ratio A_{peff0}=Aₚ₁+Aₚ₂ Aₚ₃/(Aₚ₂+Aₚ₃) and the NMOS effective ratio A_{neff0}=Aₙ₁. As V_{IN} 202 increases, V_{OUT} 204 remains high until V_{IN} 202 reaches a first threshold voltage (e.g., V_{IN}_{_{—}}_{TH0} as shown in FIG. 5), where α=α₀ and

$${α}_{0} = \sqrt{\frac{{μ}_{n} {A}_{neff 0}}{{μ}_{p} {A}_{peff 0}}} = \sqrt{\frac{{μ}_{n} {A}_{n 1}}{{μ}_{p} ( {A}_{p 1} + \frac{{A}_{p 2} {A}_{p 3}}{{A}_{p 2} + {A}_{p 3}} )}}$$

where μₙ and μₚ are the electron and hole mobilities, respectively.

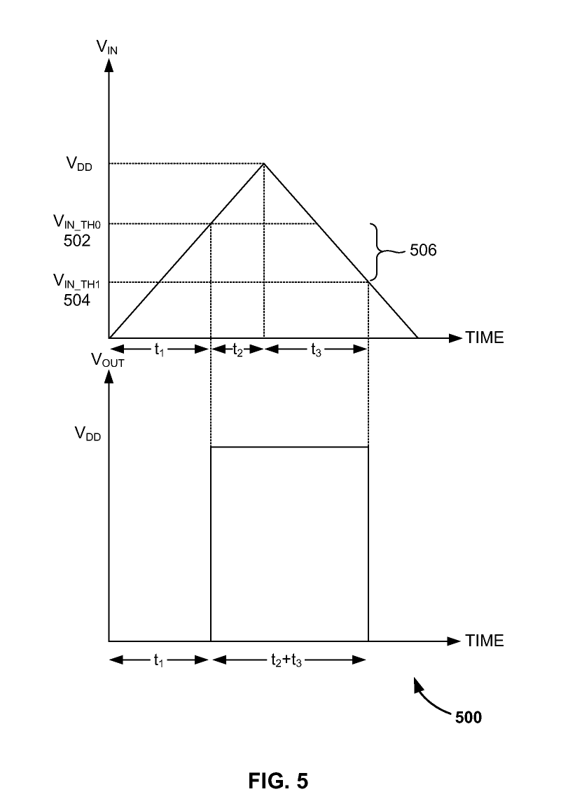

FIG. 4 illustrates the CMOS comparator circuit 200 of FIG. 2 when the input voltage V_{IN} 202 is equal to the supply voltage V_{DD} 206; the first PMOS transistor 208, the second PMOS transistor 210, and the third PMOS transistor 212 are off; the first NMOS transistor 214, the second NMOS transistor 216, and the third NMOS transistor 218 are on; and the output voltage V_{OUT} 204 is equal to the supply voltage V_{DD} 206. The input voltage V_{IN} 202 may be increased beyond the first threshold voltage. When the input voltage V_{IN} 202 becomes equal to the supply voltage V_{DD} 206, the first PMOS transistor 208, the second PMOS transistor 210, and the third PMOS transistor 212 switch off (e.g., reverse biased), and the first NMOS transistor 214, the second NMOS transistor 216, and the third NMOS transistor 218 switch on (e.g., forward biased). Thus, V_{X} 222 becomes approximately equal to the voltage of ground 220. Since V_{X} 222 is coupled to the input of the inverter 224, V_{OUT}=V_{DD}. Now, α=α₁, which is expressed as:

$${α}_{1} = \sqrt{\frac{{μ}_{n} {A}_{neff 0}}{{μ}_{p} {A}_{peff 0}}} = \sqrt{\frac{{μ}_{n} ( {A}_{n 1} + \frac{{A}_{n 2} {A}_{n 3}}{{A}_{n 2} + {A}_{n 3}} )}{{μ}_{p} {A}_{p 1}}}$$

FIG. 5 is a hysteresis graph 500 illustrating a first threshold voltage 502, a second threshold voltage 504, and a hysteresis width 506 of the CMOS comparator circuit 200 of FIG. 2. The hysteresis graph 500 traces the difference in output (e.g., V_{OUT}) for any given input (e.g., V_{IN}) with respect to time. When the input voltage 202 (e.g., V_{IN}) is zero, the output voltage 204 (e.g., V_{OUT}) is also equal to zero. The input voltage V_{IN} 202 may be increased from zero to a first threshold level V_{IN}_{_{—}}_{TH0} 502 during a time t₁, at which point the output voltage V_{OUT} 204 becomes equal to the supply voltage V_{DD} 206. The input voltage V_{IN} 202 may then be further increased to become equal to the supply voltage V_{DD} 206 during a time t₂. The output voltage V_{OUT} 204 may then remain equal to the supply voltage V_{DD} 206. Furthermore, the input voltage V_{IN} 202 may then be decreased from the supply voltage V_{DD} 206 until a second threshold level V_{IN}_{_{—}}_{TH1} 504 is reached, during a time t₃. The first threshold voltage level V_{IN}_{_{—}}_{TH0} 502 is given by:

$${V}_{IN\_TH 0} = \frac{{α}_{0} {V}_{TN} + VDD + {V}_{TP}}{1 + {α}_{0}}$$

and the second threshold voltage level V_{IN}_{_{—}}_{TH1} 504 is given by:

$${V}_{IN\_TH 1} = \frac{{α}_{1} {V}_{TN} + VDD + {V}_{TP}}{1 + {α}_{1}} .$$

Therefore, α₁>α₀, because V_{IN}_{_{—}}_{TH1}<V_{IN}_{_{—}}_{TH0}. The difference between the first threshold level V_{IN}_{_{—}}_{TH0} 502 and the second threshold level V_{IN}_{_{—}}_{TH1} 504 may be expressed as the hysteresis width 506. The hysteresis width 506 is expressed as:

$$hysteresis width = {V}_{IN\_TH 0} - {V}_{IN\_TH 1} = \frac{{α}_{0} {V}_{TN} + VDD + {V}_{TP}}{1 + {α}_{0}} - \frac{{α}_{1} {V}_{TN} + VDD + {V}_{TP}}{1 + {α}_{1}}$$

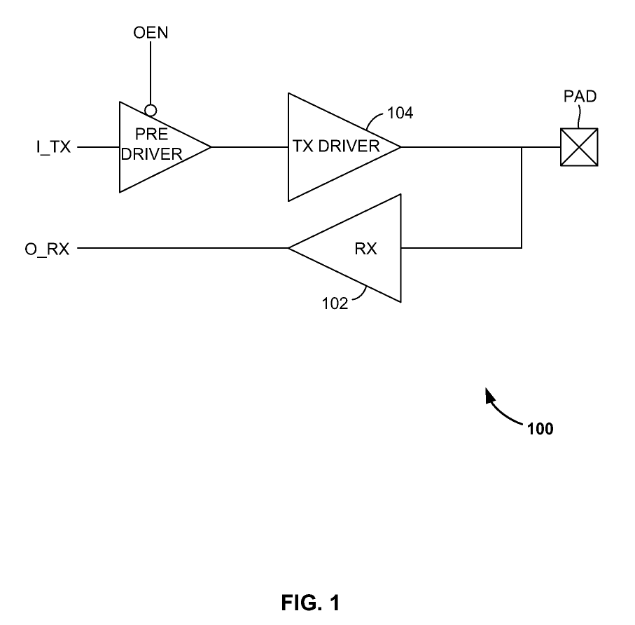

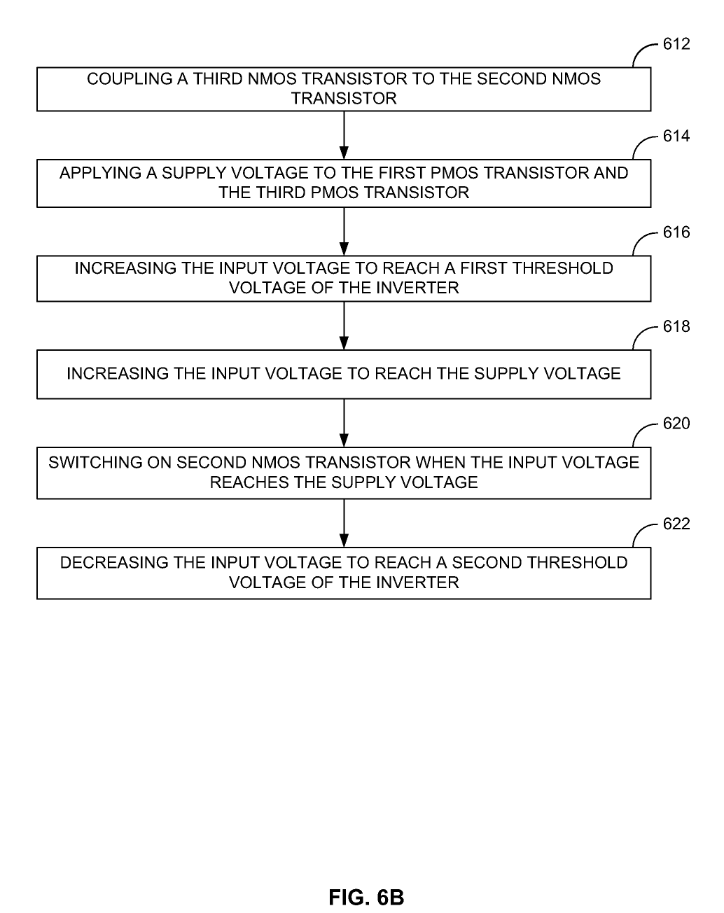

FIGS. 6A and 6B, with reference to FIGS. 1 through 5, are interrelated process flow diagrams illustrating a method of providing a hysteresis window (e.g., hysteresis width 506 of FIG. 5) in a CMOS comparator circuit 200 according to an embodiment herein, wherein the method comprises: applying (602) a low input voltage to a first p-type metal-oxide-semiconductor (PMOS) transistor 208 and a first n-type metal-oxide-semiconductor (NMOS) transistor 214 (e.g., as shown in FIG. 3); coupling (604) an inverter 224 to an output of the first PMOS transistor 208 and an output of the first NMOS transistor 214; coupling (606) a second NMOS transistor 216 in parallel with the first NMOS transistor 214 and a second PMOS transistor 210 in parallel with the first PMOS transistor 208, the second PMOS transistor 210 and the second NMOS transistor 216 coupled to an output voltage (e.g., as shown in FIGS. 2, 3 and 4); switching (608) on the second PMOS transistor 210 when the output voltage is low, and coupling (610) a third PMOS transistor 212 to the second PMOS transistor 210.

In step 602, a low input voltage is applied to a first p-type metal-oxide-semiconductor (PMOS) transistor 208 and a first n-type metal-oxide-semiconductor (NMOS) transistor 214 (e.g., as shown in FIG. 3). In step 604, an inverter 224 is coupled to an output of the first PMOS transistor 208 and an output of the first NMOS transistor 214. In step 606, a second NMOS transistor 216 is coupled in parallel with the first NMOS transistor 214 and a second PMOS transistor 210 in parallel with the first PMOS transistor 208, the second PMOS transistor 210 and the second NMOS transistor 216 coupled to an output voltage (e.g., as shown in FIGS. 2, 3 and 4). In step 608, the second PMOS transistor 210 is switched on when the output voltage is low. In step 610, a third PMOS transistor 212 may be coupled to the second PMOS transistor 210.

Referring to FIG. 6B, coupling (612) a third PMOS transistor 212 to the second PMOS transistor 210 (e.g., as shown in FIGS. 2, 3, and 4); coupling (614) a third NMOS transistor 218 to the second NMOS transistor 220 (e.g., as shown in FIGS. 2, 3, and 4); applying (616) a supply voltage to the first PMOS transistor 208 and the third PMOS transistor 212; increasing (618) the input voltage to reach a first threshold voltage of the inverter 224 (e.g., increasing to first threshold level V_{IN}_{_{—}}_{TH0} 502 as shown in FIG. 5); switching (620) on second NMOS transistor 216 when the input voltage reaches the supply voltage, and decreasing (622) the input voltage to reach a second threshold voltage of the inverter 224 (e.g., from first threshold level V_{IN}_{_{—}}_{TH0} 502 to second threshold level V_{IN}_{_{—}}_{TH1} 504 as shown in FIG. 5).

In step 612, a third PMOS transistor 212 may be coupled to the second PMOS transistor 210 (e.g., as shown in FIGS. 2, 3 and 4). In step 614, a third NMOS transistor 218 may be coupled to the second NMOS transistor 216 (e.g., as shown in FIGS. 2, 3 and 4). In step 616, a supply voltage may be applied to the first PMOS transistor 208 and the third PMOS transistor 212. In step 618, the input voltage may be increased to reach a first threshold voltage of the inverter 224 (e.g., increasing to first threshold level V_{IN}_{_{—}}_{TH0} 502 as shown in FIG. 5). In step 620, second NMOS transistor 216 may be switched on when the input voltage reaches the supply voltage. In step 622, the input voltage may be decreased to reach a second threshold voltage of the inverter 224 (e.g., from first threshold level V_{IN}_{_{—}}_{TH0} 502 to second threshold level V_{IN}_{_{—}}_{TH1} 504 as shown in FIG. 5).

The techniques provided by the embodiments herein may be implemented on an integrated circuit chip (not shown) and may be used in any digital IO PAD with hysteresis is desired at no static current. The invention can also be used as an analog comparator with hysteresis in relaxation oscillators. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The CMOS comparator circuit 200 avoids false triggering when transition takes place from logic “0′” to “1” or from “1” to “0”. When the output of the inverter is “1”, the effective aspect ratio of the NMOS transistor 214 is increased by turning on a second NMOS transistor 216, and a threshold voltage of the inverter 224 is decreased, and when the digital output of the inverter 224 is “0”, the effective aspect ratio of the PMOS transistor 208 is increased by turning on a second PMOS transistor 210, and the threshold voltage of the inverter 224 is increased. Thus, it is able to provide a sufficient hysteresis window to noise signal without affecting the digital output. The CMOS comparator circuit 200 is particularly advantageous in applications where comparators with zero static currents are needed while providing a sufficient hysteresis window such as digital IO pads and relaxation oscillators.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A complementary metal oxide semiconductor (CMOS) comparator circuit comprising:
a plurality of p-type metal-oxide-semiconductor (PMOS) transistors receiving an input voltage signal;
a plurality of n-type metal-oxide-semiconductor (NMOS) transistors operatively connected to said PMOS transistors and adapted to receive said input voltage signal; and
an inverter adapted to invert said input voltage signal into an output voltage signal;
wherein an effective aspect ratio of the PMOS and NMOS transistors are dependent on the level of said output voltage signal from said inverter,
wherein when a digital output of said inverter is “1”, said effective aspect ratio of the NMOS transistor is increased by turning on a second NMOS transistor, and a threshold voltage of said inverter is decreased, and
wherein when said digital output of said inverter is “0”, said effective aspect ratio of the PMOS is increased by turning on a second PMOS transistor, and said threshold voltage of said inverter is increased.

2. The CMOS comparator circuit of claim 1, all the limitations of which are incorporated herein by reference, further comprising:
a third PMOS transistor operatively connected in parallel with said first PMOS transistor; and
a third NMOS transistor operatively connected in parallel with said first NMOS transistor,
wherein said second NMOS transistor is coupled to said second PMOS transistor.

3. The CMOS comparator circuit of claim 1, all the limitations of which are incorporated herein by reference, wherein said second PMOS transistor and said second NMOS transistor output said output voltage.

4. The CMOS comparator circuit of claim 1, all the limitations of which are incorporated herein by reference, wherein said second PMOS transistor is switched on to increase a threshold voltage of said inverter when said output voltage is low.

5. The CMOS comparator circuit of claim 1, all the limitations of which are incorporated herein by reference, wherein a supply voltage is applied to said first PMOS transistor.

6. The CMOS comparator circuit of claim 5, all the limitations of which are incorporated herein by reference, wherein said input voltage signal is adapted to be increased from zero to a first threshold level of said inverter during a first time period at which point said output voltage signal becomes equal to said supply voltage.

7. The CMOS comparator circuit of claim 6, all the limitations of which are incorporated herein by reference, wherein said input voltage signal is further adapted to increase to become equal to said supply voltage during a second time period, wherein said output voltage signal remains equal to said supply voltage.

8. The CMOS comparator circuit of claim 7, all the limitations of which are incorporated herein by reference, wherein said input voltage signal is further adapted to decrease from said supply voltage until a second threshold level of said inverter is reached during a third time period, wherein a difference between said first threshold level of said inverter and said second threshold level of said inverter equals a hysteresis width of said CMOS comparator circuit.

9. An input-output pad comprising a complementary metal oxide semiconductor (CMOS) comparator with a hysteresis window, said CMOS comparator comprising:
a first p-type metal-oxide-semiconductor (PMOS) transistor receiving an input voltage;
an inverter coupled to a gate of said first PMOS transistor;
a second PMOS transistor operatively connected in parallel to said first PMOS transistor, wherein said second PMOS transistor is coupled to said inverter;
a first n-type metal-oxide-semiconductor (NMOS) transistor receiving an input voltage; and
a second NMOS transistor operatively connected in parallel to said first NMOS transistor, wherein said second NMOS transistor is coupled to said inverter and said second PMOS transistor, wherein said second NMOS transistor outputs an output voltage,
wherein said second PMOS transistor is switched on to increase a threshold voltage of said inverter when said output voltage is zero, and said second NMOS transistor is switched on to decrease a threshold voltage of said inverter when said output voltage is equal to a supply voltage.

10. The input-output pad of claim 9, all the limitations of which are incorporated herein by reference, further comprising:
a third PMOS transistor operatively connected in parallel with said first PMOS transistor;
a third NMOS transistor operatively connected in parallel with said first NMOS transistor,
wherein said second NMOS transistor is coupled to said second PMOS transistor.

11. The input-output pad of claim 10, all the limitations of which are incorporated herein by reference, wherein said supply voltage is applied to said first PMOS transistor and said third PMOS transistor, and wherein said second NMOS transistor switches on when said input voltage reaches said supply voltage.

12. The input-output pad of claim 11, all the limitations of which are incorporated herein by reference, wherein said input voltage is adapted to be increased from zero to a first threshold level of said inverter during a first time period at which point said output voltage becomes equal to said supply voltage.

13. The input-output pad of claim 12, all the limitations of which are incorporated herein by reference, wherein said input voltage is further adapted to increase to become equal to said supply voltage during a second time period, wherein said output voltage remains equal to said supply voltage.

14. The input-output pad of claim 13, all the limitations of which are incorporated herein by reference, wherein said input voltage is further adapted to decrease from said supply voltage until a second threshold level of said inverter is reached during a third time period, wherein a difference between said first threshold level of said inverter and said second threshold level of said inverter equals a hysteresis width of said CMOS comparator.

15. A method of providing a hysteresis window in a complementary metal oxide semiconductor (CMOS) comparator circuit comprising:
applying a low input voltage to a first p-type metal-oxide-semiconductor (PMOS) transistor and a first n-type metal-oxide-semiconductor (NMOS) transistor;
coupling an inverter to an output of said first PMOS transistor and an output of said first NMOS transistor;
coupling a second NMOS transistor in parallel with said first NMOS transistor;
coupling a second PMOS transistor in parallel with said first PMOS transistor, said second PMOS transistor and said second NMOS transistor coupled to an output voltage; and
switching on said second PMOS transistor when said output voltage is low.

16. The method of claim 15, all the limitations of which are incorporated herein by reference, further comprising:
coupling a third PMOS transistor to said second PMOS transistor;
coupling a third NMOS transistor to said second NMOS transistor; and
applying a supply voltage to said first PMOS transistor and said third PMOS transistor.

17. The method of claim 16, all the limitations of which are incorporated herein by reference, further comprising increasing said input voltage to reach a first threshold voltage of said inverter.

18. The method of claim 17, all the limitations of which are incorporated herein by reference, further comprising increasing said input voltage to reach said supply voltage.

19. The method of claim 18, all the limitations of which are incorporated herein by reference, further comprising switching on second NMOS transistor when said input voltage reaches said supply voltage.

20. The method of claim 19, all the limitations of which are incorporated herein by reference, further comprising decreasing said input voltage to reach a second threshold voltage of said inverter.
